(19) United States
(12) Patent Application Publication
(10) Pub. No.: US 2007/0114669 A1
(43) Pub. Date: May 24, 2007

(54) Plasma display panel

(76) Inventors: Yong-Su Park, Suwon-si (KR); Ki-Dong Kim, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/603,451

(22) Filed: Nov. 22, 2006

(30) Foreign Application Priority Data
Nov. 22, 2005 (KR) 10-2005-0111684

(51) Int. Cl. H01L 23/52

(52) U.S. Cl. 257/758

(57) ABSTRACT

The plasma display panel includes a first substrate and a second substrate that are disposed substantially in parallel with each other with a predetermined distance therebetween; a plurality of address electrodes disposed on the first substrate; a first dielectric layer disposed covering the address electrodes; a plurality of barrier ribs having a predetermined height from the first dielectric layer to provide a discharge cell; a phosphor layer disposed in the discharge cell; a plurality of display electrodes disposed on one side of the second substrate facing the first substrate in a direction crossing the address electrodes; a second dielectric layer disposed covering the discharge sustain electrodes; and a protective layer disposed to cover the second dielectric layer. The protective layer includes a first area having a predetermined thickness and a second area that is disposed corresponding to a display electrode area and is thicker than the first area.

### CROSS-REFERENCE TO RELATED APPLICATION

This application claims priority to and the benefit of Korean Patent Application No. 10-2005-0111684 filed in the Korean Intellectual Property Office on Nov. 22, 2005, the entire content of which is incorporated herein by reference.

### BACKGROUND OF THE INVENTION

1. Field of the Invention

The present embodiments relate to a plasma display panel (PDP). More particularly, the present embodiments relate to a plasma display panel having an excellent life-span characteristic.

2. Description of the Related Art

Plasma display panels (PDPs) display letters or graphics using light emitted from plasma which is generated upon a gas discharge.

That is, the plasma is discharged to generate ultraviolet rays upon applying a voltage to two electrodes mounted inside a discharge space of the plasma display panel, and the ultraviolet rays excite a phosphor layer formed with a certain pattern to realize a certain image.

Plasma display panels are generally composed of a lower substrate, a plurality of address electrodes disposed on the lower substrate, a dielectric layer formed on the lower substrate on which the address electrodes are formed, a plurality of barrier ribs disposed on the dielectric layer to maintain a discharge distance and to prevent crosstalk between cells, and a phosphor layer formed on the surface of the barrier ribs. A plurality of display electrodes is disposed under an upper substrate in a perpendicular direction to that of the plurality of address electrodes, with a certain distance therebetween. Then, a dielectric layer and a protective layer are formed on discharge sustain electrodes.

Particularly, the protective layer is mainly composed of MgO since it is transparent enough to transmit visible rays and is effective for protecting the dielectric layer and for emitting secondary electrons.

Since the protective layer directly contacts discharge gases, components that constitute the protective layer and properties of the protective layer may affect discharge characteristics of a PDP. Furthermore, the properties of the protective layer vary according to constituting components of the protective layer and film forming conditions.

Therefore, research on optimal components to adopt for desirable characteristics of the protective layer has been needed. The following embodiments achieve these and other advantageous characteristics.

### SUMMARY OF THE INVENTION

One embodiment provides a plasma display panel (PDP) having an improved life-span characteristic.

According to one embodiment, a plasma display panel (PDP) is provided, which includes: a first substrate and a second substrate that are disposed substantially in parallel with each other with a predetermined distance therebetween; a plurality of address electrodes disposed on the first substrate; a first dielectric layer disposed covering the address electrodes; a plurality of barrier ribs having a predetermined height from the first dielectric layer to provide a discharge cell; a phosphor layer disposed in the discharge cell; a plurality of display electrodes disposed on one side of the second substrate facing the first substrate in a direction crossing the address electrodes; a second dielectric layer disposed covering the discharge sustain electrodes; and a protective layer disposed to cover the second dielectric layer. The protective layer includes a first area having a predetermined thickness and a second area that is disposed corresponding to a display electrode area and is thicker than the first area.

The protective layer includes a first protective layer having a predetermined thickness and a second protective layer that is disposed corresponding to a display electrode area and is thicker than the first area.

The first and second areas and the first and second protective layers may crystalline phases from each other, resulting in a separating interface area therebetween.

### BRIEF DESCRIPTION OF THE DRAWINGS

FIG. 1 shows over-etching of the protective layer of the conventional panel (PDP);

FIG. 2 is a partially exploded perspective view showing a plasma display accordance with an embodiment; and

FIG. 3 is a schematic cross-sectional view showing the second substrate e embodiment.

### DETAILED DESCRIPTION OF THE INVENTION

An exemplary embodiment will hereinafter be described in detail with accompanying drawings.

The stability of surface discharge in a plasma display panel (PDP) is determined based on aging.

The surface of the protective layer sustained in the plasma discharge is etched by activation of the PDP and ion impact. The extent of etching increases as discharge time, passes. When the etching of the protective layer by the discharge between the electrodes is observed with a disparity scanning electron microscope (SEM), it can be seen that etching and re-deposition occur in the protective layer.

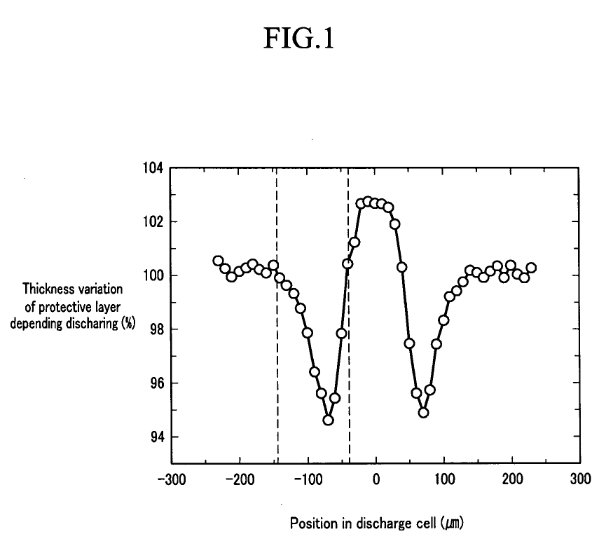

FIG. 1 shows over-etching of the protective layer of the conventional PDP.

In FIG. 1, the X-axis denotes the position, or range, from the center of in a side cross-section of the PDP. 0 signifies the center of the discharge ft part (−) of 0 denotes a sustain electrode direction (hereinafter, X electrode), ht part (+) denotes a scan electrode direction (hereinafter, Y electrode). Also, otes a thickness variation ratio (%) of the protective layer before and after thickness variation ratio is calculated based on the following Equation 1.

$$ThicknessVariation ( \% ) = \frac{T 2}{T 1} \times 100 \qquad Eqaution 1$$

T1: Thickness of a protective layer before discharging
T2: Thickness of a protective layer after discharging

It can be shown from FIG. 1 that the etching is centered in an area ranging from about 40 to about 140 μm toward either side from the 0 point of the X axis. The position belongs to an area where the sustain electrodes (hereinafter, X electrodes) and the scan electrodes (hereinafter, Y electrodes) are formed. Also, it can be seen that the re-deposition occurs in an area ranging from about −40 to about 40 μm, that is, between the X electrodes and the Y electrodes.

According to an embodiment, the life-span characteristic of the PDP can be effectively improved by making the protective layer thick in the area where the over-etching occurs, which is an area where the display electrode is formed, to thereby resolve the problem of non-uniform etching.

According to one embodiment, a PDP includes: a first substrate and a second substrate that are disposed substantially in parallel with each other with a predetermined distance therebetween; a plurality of address electrodes disposed on the first substrate; a first dielectric layer disposed covering the address electrodes; a plurality of barrier ribs having a predetermined height from the first dielectric layer to provide a discharge cell; a phosphor layer disposed in the discharge cell; a plurality of display electrodes disposed on one side of the second substrate facing the first substrate in a direction crossing the address electrodes; a second dielectric layer disposed covering the discharge sustain electrodes; and a protective layer disposed to cover the second dielectric layer.

The protective layer includes a first area having a predetermined thickness and a second area that is disposed corresponding to a display electrode area and that is thicker than the first area. The protective layer at the second area is from about 100 to about 800 Å thicker than that at the first area. According to one embodiment, the protective layer at the second area is from about 250 to about 500 Å thicker than that at the first area. According to another embodiment, the protective layer at the second area is from about 300 to about 400 Å thicker than that at the first area.

According to another embodiment, the protective layer includes a first protective layer and a second protective layer that is disposed corresponding to a display electrode area.

The second protective layer may be disposed corresponding to an area between bus electrodes of the display electrode.

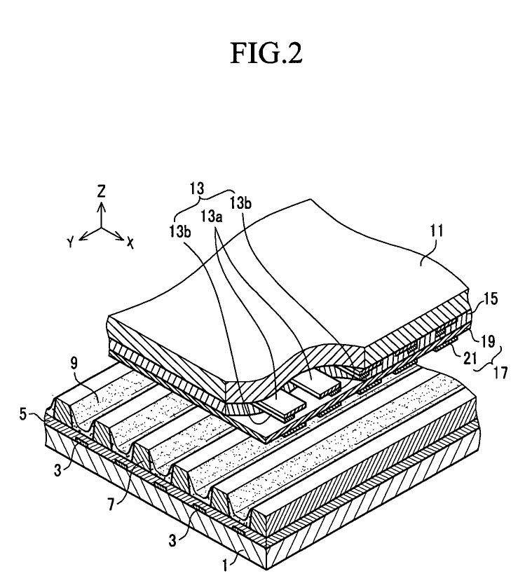

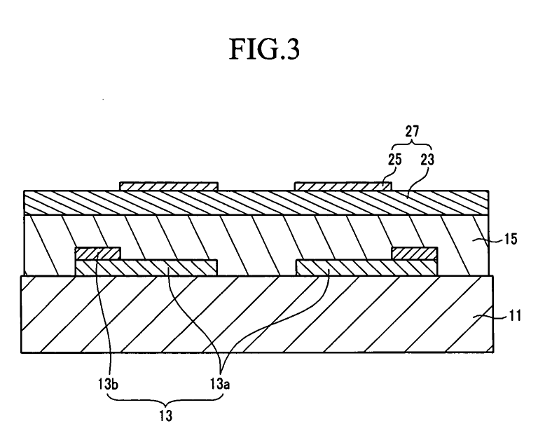

FIG. 2 is a partial exploded perspective view showing a PDP in accordance with an embodiment, and FIG. 3 is a schematic cross-sectional view showing the second substrate according to one embodiment. However, the PDP of the present embodiments is not limited to the structures illustrated in FIGS. 2 and 3.

As shown FIG. 2 and FIG. 3, the PDP of the present embodiment includes a first substrate 1 , which will be referred to as a lower substrate, hereinafter, and a second substrate 11, which will be referred to as an upper substrate, hereinafter. The lower substrate 1 and the upper substrate 11 face each other and are sealed together, and the space between the lower substrate 1 and the upper substrate 11 is filled with a discharge gas. A plurality of barrier ribs 7 are disposed in the space between the lower substrate 1 and the upper substrate 11 to thereby form a plurality of discharge cells. The discharge cells include phosphors 9 of red R, green G, and blue B colors.

Display electrodes 13 are disposed on the upper substrate 11 along the x-axis direction of the drawing, with a space corresponding to each discharge cell in the y-axis direction between them. In the lower substrate 1, address electrodes 3 are formed in a direction crossing the display electrodes 13, the y-axis direction. The address electrodes 3 are disposed with a space corresponding to each discharge cell in the x-axis direction between them the display electrodes 13 and the address electrodes 3 are disposed confronting and crossing each other in each discharge cell.

The barrier ribs 7 disposed between the upper substrate 11 and the lower substrate 1 are disposed in parallel with a predetermined space between them. The barrier ribs 7 partition the space between the upper substrate 11 and the lower substrate 1 to thereby form the discharge cells for plasma discharge.

FIG. 2 illustrates a stripe-type barrier rib structure where the barrier ribs 7 are formed in a direction parallel to the address electrodes 3, which is the y-axis direction. However, the barrier rib structure of the present embodiment is not limited to the stripe type. The barrier rib structure may be a closed barrier rib structure where first barrier ribs 7 are formed in a direction parallel to the address electrodes 3 (the y-axis direction), and second barrier ribs 7 (not shown) are formed in a direction crossing the first barrier ribs (the x-axis direction) to thereby form independent and closed discharge cells, or the barrier rib structure may be a closed barrier rib structure where the discharge cells are formed in the form of, for example, square, hexagon, or octagon.

Since the address electrodes 3 are typically formed in the lower substrate 1, the address electrodes 3 are formed in the lower substrate 1 in the present embodiment. However, the present embodiments are not limited to this, and the address electrodes 3 may be formed in the upper substrate 11 or the barrier ribs 7. The address electrodes 3 are covered with a first dielectric layer 5 to generate wall charges in the discharge cells, and the barrier ribs 7 are formed on the first dielectric layer 5.

The display electrodes 13 are composed of sustain electrodes and scan electrodes facing each other in both sides of the discharge cells. They are formed in the upper substrate 11. Although this embodiment exemplifies the upper substrate 11 to include the sustain electrodes and the scan electrodes, the upper substrate 11 may further include a middle electrode (not shown) between the sustain electrodes and scan electrodes of the display electrodes 13 for scanning and addressing.

Each of the sustain electrodes and the scan electrodes may be composed of a first electrode 13a and a second electrode 13b, or it may be formed of only the first electrode 13a or the second electrode 13b. When the upper substrate includes the middle electrode (not shown), the middle electrode may be formed of the same material as that of the sustain electrode and the scan electrode to simplify the manufacturing process. The first electrode 13a may be a stripe type extending in a direction crossing the address electrodes 3 (x-axis direction). Also, the first electrode 13a is an element that causes surface discharge inside of the discharge cells. Since it occupies a considerable area of a discharge cell, it is desirable to form the first electrode 13a of a transparent material to minimally block visible light and secure luminance. The first electrode 13a may be formed of indium tin oxide (ITO).

The second electrode 13b compensates for the high resistance of the first electrode 13a to secure electrical conductivity of the first electrode 13a. It is desirable to form the second electrode 13b of a metal having an excellent electrical conductivity. The second electrode 13b may be formed of at least one selected from the group consisting of silver (Ag), gold (Au), aluminum (Al), copper (Cu), nickel (Ni), chromium (Cr), a silver-palladium alloy (Ag—Pd), and combinations or alloys thereof. The second electrode 13b is formed in the form of a stack on the first electrode 13a on top of the upper substrate 11 in a direction crossing the address electrodes 3 (the x-axis direction). Also, since the second electrode 13b is formed of an opaque material, it is disposed opposite to the barrier ribs 7. The second electrode 13b may be formed to have a smaller width than the width of the barrier ribs 7 to thereby minimally block the visible light emitted in the discharge cell.

The display electrodes 13 are covered with a second dielectric layer 15 to accumulate wall charges. Also, a protective layer 17 may be formed on the second dielectric layer 15 to prevent the second dielectric layer 15 from being collided with and damaged by ions separated by plasma and to better emit secondary electrons when the ions collide.

The PDP of the present embodiment includes the protective layer 17 covering the second dielectric layer 15 on the top, and the protective layer 17 includes a first region 19 having a predetermined thickness and a second region 21 that is thicker than the first region 19 and is formed in a region corresponding to the display electrodes.

Since different crystals exist in the first region and the second region, which have a different thickness, there is an interface between them.

According to another embodiment illustrated in FIG. 3, a PDP can include a dual protective layer 27, which is composed of a first protective layer 23 to cover the second dielectric layer 15 and a second protective layer 25 on top of the first protective layer 23 in a region corresponding to the display electrodes 13. As illustrated in FIG. 3, the second protective layer 25 may be formed in a region corresponding to the first electrode 13abetween two second electrodes 13b on top of the first protective layer 23.

Since the first protective layer and the second protective layer are formed of different crystals, there is an interface between them. The life-span characteristic of the PDP can be improved by making a thick protective layer in the region where the display electrodes 13 are disposed on the second dielectric layer 15 or adding a second protective layer 25 thereto to thereby prevent non-uniform over-etching of the protective layers 17 and 27 in the region where the display electrodes 13 are disposed.

The first protective layer may have a thickness of a conventional protective layer. Its thickness is not limited to a specific thickness but it may be from about 3000 to 10,000 Å, preferably from about 4000 to about 8000 Å.

Also, the thickness of the second protective layer may be from about 200 preferably from about 300 to about 400 Å.

The protective layer may be formed of metal oxide such as, for example, CaO, Al₂O₃, Fe₂O₃, Na₂O, MgO, SrGdOₓ, SrCaOₓ, ZnO, SrO, SiO₂, La₂O₃, or a combination therefore, where x is determined according to stoichiometry. The first protective layer and the second protective layer may be formed of the same material or different materials.

When the protective layer is formed in two layers, it is desirable to form the first protective layer of MgO, which is durable and has a high secondary electron emission coefficient, and form the second protective layer of at least one selected from the group consisting of SrGdOₓ, SrCaOₓ, and combinations thereof (where x is determined stoichiometry).

Also, the MgO material may be monocrystalline or polycrystalline. A sintered polycrystalline MgO material has advantages that the response rate is quick, and it is possible to quantitatively dope a specific element to improve discharge characteristics, while its amount can be freely controlled within the solid-solution limit. A fused monocrystalline MgO material has a relatively slow response time compared to the polycrystalline MgO material, but it has advantages that it has a high discharge stability and excellent temperature resistance.

In the plasma display panel as above, wall charges are formed on the dielectric layer by receiving a driving voltage from the electrodes and causing address discharge between the electrodes. Also, sustain discharge occurs between the electrodes by alternating current signals, which are alternately supplied to a pair of electrodes formed in the second substrate, in the discharge cells selected by the address discharge. Accordingly, ultraviolet rays are generated as the discharge gas filling the discharge space where the discharge cells are formed is excited and shifts. The ultraviolet rays excite phosphors to thereby generate visible light and form an image.

Since the various manufacturing methods of PDPs are widely known to those skilled in the art, a detailed description thereof will not be provided herein. The fabrication process of the protective layer, will be described in detail.

According to the present embodiment, a protective layer of a predetermined thickness is formed of a protective layer-forming composition on the upper substrate with a second dielectric layer formed therein, and a greater amount of the composition is applied in regions corresponding to the display electrodes. Herein, a mask is disposed in the upper substrate except the region corresponding to the display electrodes to thereby make the protective layer of the region thick.

Also, when the protective layer is formed in two layers, a first protective layer is formed of the first protective layer-forming composition on the upper substrate with the second dielectric layer formed therein, and a second protective layer is formed of a second protective layer-forming composition on the region corresponding to the display electrodes on the first protective layer.

Herein, the first protective layer-forming composition and the second protective layer-forming composition include at least one metal oxide, which are described above.

The first protective layer-forming composition and the second protective layer-forming composition may further include an additive typically used to improve the characteristics of the protective layer. Examples of the additive include at least one selected from the group consisting of MgO, MgF₂, CaF₂, LiF, Al₂O₃, ZnO, CaO, SrO, SiO₂, and La₂O₃.

The method for forming the protective layer is not limited to a specific method, and the protective layer may be formed by, for example, a thick-layer printing method using a paste, or by a deposition method. Among the methods, the deposition method is relatively resistant to sputtering based on ion impact, and it can reduce the sustain voltage based on the emission of secondary voltage and initial voltage.

When the protective layer is formed in the deposition method, the deposition method may be magnetron sputtering, electron beam deposition, ion beam assisted deposition (IBAD), chemical vapor deposition (CVD), a method of forming a layer by ionizing evaporated particles, or ion plating, which has similar characteristics to sputtering in respect of a close contacting property and crystals of the protective layer but has an advantage that the deposition rate is as fast as about 8 nm/s. Among them, the electron beam deposition is preferred.

According to the present embodiment, the PDP can have an excellent life-span characteristic by forming the protective layer thick in the region corresponding to the display electrodes or disposing a second protective layer in the region corresponding to the display electrodes on top of the first protective layer to thereby prevent non-uniform over-etching of the protective layer during discharge.

The following examples illustrate the present embodiments in more detail. However, it is understood that the present embodiments are not limited by these examples.

### EXAMPLE 1

A soda lime glass substrate was sputtered with indium tin oxide and laminated with a dry film resist (DFR). The soda lime glass substrate with the DFR was laminated again with a patterned photo mask on top of the DFR and then exposed to high voltage mercury. Subsequently, it was developed with a Na₂CO₃ (0.4% alkali aqueous solution), dried, and patterned in the form of a transparent electrode. The soda lime glass substrated was etched with hydrochloric acid and nitric acid. Then, the DFR pattern part was separated out by using NaOH (5.0% aqueous solution), and baked to thereby form a transparent electrode, i.e., a first electrode. The transparent electrode was coated with a composition for forming a bus electrode, which includes Cr—Cu—Cr, dried, and exposed to light by using a direct imaging (DI) exposer. The drying and exposure were repeated more than five times, and the transparent electrode was developed with (Na₂CO₃ 0.4% alkali aqueous solution) and baked to thereby form a stripe-type bus electrode thereon. The transparent electrode including the bus electrode thereon was a display electrode.

Subsequently, the substrate with the display electrode formed thereon was coated with a second dielectric layer-forming composition that includes PbO—B₂O₃—SiO₂ glass powder, dried, and baked to thereby form the second dielectric layer.

A first protective layer having a thickness of 7000 Å was formed by depositing a sintered MgO material on the second dielectric layer in an electron beam deposition method. Subsequently, a second protective layer having a thickness of 200 Å was formed in a region corresponding to the display electrodes on top of the first protective layer by depositing SrCaOₓ in the electron beam deposition method, to thereby complete the preparation of an upper substrate. During the electron beam deposition, the vacuum level was 1.0×10⁻⁹ Pa, and oxygen gas partial pressure was 1.0×10⁻² Pa, while substrate temperature was 200° C. and layer formation speed was 20 Å/sec.

A lower substrate was prepared by forming address electrodes, a first dielectric layer, barrier ribs, and a phosphor layer on another soda lime substrate. Then, a PDP was fabricated by sealing the upper substrate to the lower substrate, exhausting the air in the discharge cells, and injecting a discharge gas at 400 Torr therein.

### Comparative Example 1

A PDP was fabricated in the same method as in Example 1, except that a protective layer was formed on top of the second dielectric layer in a thickness of 6000 Å by depositing a sintered MgO material only once.

The etching rates of the protective layers of the PDPs fabricated according to Example 1 and Comparative Example 1 were measured before and after discharge. Then, life-span characteristics of the PDPs were estimated based on the etching rates.

The result showed that the PDP of Example 1 having a dual protective layer had a remarkably decreased etching rate, compared to the PDP of Comparative Example 1 having a single protective layer. It can be seen from the result that the PDP of Example 1 has superior life-span characteristics to that of the PDP of Comparative Example 1.

The protective layer according to one embodiment can prevent non-uniform over-etching and thereby improve life-span characteristics of a PDP.

While these embodiments have been described in connection with what is presently considered to be practical exemplary embodiments, it is to be understood that the embodiments are not limited to the disclosed embodiments, but, on the contrary, are intended to cover various modifications and equivalent arrangements included within the spirit and scope of the appended claims.

What is claimed is:

1. A plasma display panel (PDP), comprising:
a first substrate and a second substrate that are disposed substantially in parallel with each other with a predetermined distance therebetween;
a plurality of address electrodes disposed on the first substrate;
a first dielectric layer disposed covering the address electrodes;
a plurality of barrier ribs having a predetermined height from the first dielectric layer configured to provide a discharge cell;
a phosphor layer disposed in the discharge cell;
a plurality of display electrodes disposed on one side of the second substrate facing the first substrate in a direction crossing the address electrodes;
a second dielectric layer disposed covering the discharge sustain electrodes; and
a protective layer disposed to cover the second dielectric layer,
wherein the protective layer includes a first area having a predetermined thickness and a second area disposed corresponding to a display electrode area which is thicker than the first area.

2. The plasma display panel of claim 1, wherein the second area is from about 100 to about 800 Å thicker than the first area.

3. The plasma display panel of claim 1, wherein the first area has a different crystalline phase from the second area, and a separating interface area exists between the first area and second area.

4. The plasma display panel of claim 1, further comprising a second dielectric layer and a second protective layer that is disposed corresponding to a display electrode area.

5. The plasma display panel of claim 4, wherein the second protective layer is disposed corresponding to an area between bus electrodes of the display electrode.

6. The plasma display panel of claim 4, wherein the second protective layer has a thickness from about 250 to about 500 Å.

7. The plasma display panel of claim 4, wherein the second protective layer has a thickness from about 300 to about 400 Å.

8. The plasma display panel of claim 4, wherein the second protective layer comprises at least one selected from the group consisting of CaO, Al₂O₃, Fe₂O₃, Na₂O, MgO, SrGdOₓ, SrCaOₓ, ZnO, SrO, SiO₂, La₂O₃, and combinations or alloys thereof, wherein x is determined according to stoichiometry.

9. The plasma display panel of claim 8, wherein the second protective layer comprises at least one selected from the group consisting of SrGdOₓ, SrCaOₓ, and combinations thereof, wherein x is determined according to stoichiometry.

10. The plasma display panel of claim 4, wherein the first protective layer has a thickness from about 3000 to about 10,000 Å.

11. The plasma display panel of claim 4, wherein the first protective layer comprises at least one selected from the group consisting of CaO, Al₂O₃, Fe₂O₃, Na₂O, MgO, SrGdOₓ, SrCaOₓ, ZnO, SrO, SiO₂, La₂O₃, and combinations or alloys thereof, wherein x is determined according to stoichiometry.

12. The plasma display panel of claim 1, wherein the protective layer comprises at least one selected from the group consisting of CaO, Al₂O₃, Fe₂O₃, Na₂O, MgO, SrGdOₓ, SrCaOₓ, ZnO, SrO, SiO₂, La₂O₃, and combinations or alloys thereof, wherein x is determined according to stoichiometry.

13. The plasma display panel of claim 12, wherein the protective layer comprises MgO.

14. A method of manufacturing a protective layer comprising:
providing an upper substrate comprising a second dielectric layer formed therein and display electrodes;
providing a protective layer-forming composition;
and applying a greater amount of the protective layer-forming composition in regions of the second dielectric layer corresponding to the display electrodes.

15. The method of claim 14, further comprising the step of providing a mask on the upper substrate which exposes the region corresponding to the display electrodes;
and applying the protective layer-forming composition to the mask, wherein the resulting protective layer is thicker in the regions corresponding to display electrodes than regions that do not correspond to display electrodes.

16. The method of claim 14, wherein the protective layer-forming composition includes at least one metal oxide.

17. The method of claim 16, wherein the metal oxide comprises at least one of CaO, Al₂O₃, Fe₂O₃, Na₂O, MgO, SrGdOₓ, SrCaOₓ, ZnO, SrO, SiO₂, La₂O₃, and combinations or alloys thereof, wherein x is determined according to stoichiometry.

18. The method of claim 14, wherein the protective layer-forming composition further comprises an additive configured to improve the characteristics of the protective layer.

19. The method of claim 18, wherein the additive comprises at least one of MgO, MgF₂, CaF₂, LiF, Al₂O₃, ZnO, CaO, SrO, SiO₂, La₂O₃, and combinations thereof.
